(19) United States
(12) Patent Application Publication
(10) Pub. No.: US 2024/0396517 A1
(43) Pub. Date: Nov. 28, 2024

(54) ACOUSTIC WAVE DEVICES WITH MULTILAYER PIEZOELECTRIC SUBSTRATE

(71) Applicant: Skyworks Solutions, Inc., Irvine, CA (US)

(72) Inventor: Rei Goto, Osaka-Shi (JP)

(21) Appl. No.: 18/671,748

(22) Filed: May 22, 2024

Related U.S. Application Data
(60) Provisional application No. 63/468,999, filed on May 25, 2023.

(51) Int. Cl. H03H 9/02; H03H 9/145; H03H 9/25

(52) U.S. Cl. CPC H03H 9/02559; H03H 9/02834; H03H 9/145; H03H 9/25

(57) ABSTRACT

An acoustic wave resonator is disclosed. The acoustic wave resonator includes a multi-layer piezoelectric substrate including a base layer, an intermediate layer, and a piezoelectric layer with lithium niobate (LiNbO3) having a cut angle ranging from 20 to 40 degrees. The acoustic wave resonator includes interdigital transducer electrodes that are in electrical communication with the piezoelectric layer.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/468,999, filed May 25, 2023, titled “ACOUSTIC WAVE DEVICES WITH MULTILAYER PIEZOELECTRIC SUBSTRATE,” are hereby incorporated by reference under 37 CFR 1.57 in their entirety.

### BACKGROUND

### Field

Embodiments of the disclosure relate to surface acoustic wave devices, and multi-layer piezoelectric substrate surface acoustic wave devices with improved coupling coefficient and temperature coefficient of frequency.

### Description of the Related Technology

An acoustic wave filter can include a plurality of resonators arranged to filter a radio frequency signal. Example acoustic wave resonators include surface acoustic wave (SAW) resonators and bulk acoustic wave (BAW) resonators. A surface acoustic wave resonator can include an interdigital transductor electrode on a piezoelectric substrate. The surface acoustic wave resonator can generate a surface acoustic wave on a surface of the piezoelectric layer on which the interdigital transductor electrode is disposed. A multi-mode SAW filter can include a plurality of longitudinally coupled interdigital transducer electrodes positioned between acoustic reflectors. Temperature compensated (TC) SAW resonators and multi-layer piezoelectric substrate (MPS) SAW resonators are examples of SAW devices.

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, three acoustic wave filters can be arranged as a triplexer. As another example, four acoustic wave filters can be arranged as a quadplexer.

MPS SAW devices can enable relatively high coupling coefficient. However, it can be challenging to achieve a relatively high temperature coefficient of frequency and quality factor, while enabling the relatively high coupling coefficient.

### BACKGROUND

The innovations described in the claims each have several aspects, no single one of which is solely responsible for its desirable attributes. Without limiting the scope of the claims, some prominent features of this disclosure will now be briefly described.

In a first aspect, an acoustic wave resonator is disclosed. The acoustic wave resonator includes a multi-layer piezoelectric substrate (MPS). The multi-layer piezoelectric substrate includes a base layer, an intermediate layer and a piezoelectric layer. The intermediate layer is disposed on the base layer. The piezoelectric layer is disposed on the intermediate layer. The acoustic wave resonator also includes a plurality of interdigital transducer electrodes in electrical communication with the piezoelectric layer.

The piezoelectric layer can be made of lithium niobate (LiNbO3). The piezoelectric layer can have a crystal orientation rotated 30 degree Y-cut X-propagation LiNbO3. A rotated angle of the crystal orientation can be in a range from 20 to 40 degree. In other words, the lithium niobate (LiNbO3) layer can be rotated in a range from 20 to 40 degree.

The piezoelectric layer can have a thickness in a range from 0.02 L to 0.38 L. L is the wavelength of the main acoustic wave excited by the acoustic wave resonator.

The intermediate layer can be made of silicon dioxide (SiO2). The intermediate layer can have a thickness in a range from 0.2 L to 0.6 L. L is the wavelength of the main acoustic wave excited by the acoustic wave resonator.

The plurality of interdigital transducer electrodes can have a thickness in a range from 0.04 L to 0.16 L. Thereby, L is the wavelength of the main acoustic wave excited by the acoustic wave resonator.

Tip areas of electrode fingers of the plurality of interdigital transducer electrodes can have a greater thickness than a central area of the electrode fingers of the plurality of interdigital transducer electrodes.

Tip areas of electrode fingers of the plurality of interdigital transducer electrodes can have a greater length than a central area of the electrode fingers of the plurality of interdigital transducer electrodes.

The plurality of interdigital transducer electrodes can be selected from the group of: aluminum (Al), copper (Cu), molybdenum (Mo), tungsten (W), platinum (Pt), and titanium (Ti).

The plurality of interdigital transducer electrodes may comprise two layers, one layer being made of aluminum and the other layer being made of molybdenum (Mo).

The plurality of interdigital transducer electrodes can include a bus bar.

The acoustic wave resonator can further comprise a partial bottom silicon dioxide (SiO2) layer partially disposed between the MPS and the plurality of interdigital transducer electrodes.

The acoustic wave resonator can further comprise a silicon nitride (SiN) layer partially coating the plurality of interdigital transducer electrodes. The silicon nitride (SiN) layer can be disposed on a central area of the electrode fingers of the plurality of interdigital transducer electrodes and on an end region of the plurality of interdigital transducer electrodes.

The acoustic wave resonator can further comprise a silicon dioxide (SiO2) layer partially coating the plurality of interdigital transducer electrodes. The silicon dioxide (SiO2) layer can be disposed on a tip area of the electrode fingers of the plurality of interdigital transducer electrodes.

The base layer can be selected from the group of: silicon (Si), silicon carbide (SiC), quartz (Qz), Poly-Si/Si, a-Si/Si, and silicon nitride (SiN/Si).

The multi-layer piezoelectric substrate can consist of the base layer, the intermediate layer, and the piezoelectric layer. That means the acoustic wave resonator can be configured without a coating over the plurality of interdigital transducer electrodes, for example.

In a second aspect, a radio frequency module is disclosed. The radio frequency module includes an acoustic wave resonator. The acoustic wave resonator includes a multi-layer piezoelectric substrate (MPS). The multi-layer piezoelectric substrate includes a base layer, an intermediate layer and a piezoelectric layer. The intermediate layer is disposed on the base layer. The piezoelectric layer is disposed on the intermediate layer. The acoustic wave resonator also includes a plurality of interdigital transducer electrodes in electrical communication with the piezoelectric layer.

The radio frequency module can be configured as a front end module.

The acoustic wave resonator can be configured as a surface acoustic wave (SAW) resonator.

In a third aspect, a wireless communication device is disclosed. The wireless communication device includes a radio frequency module including an acoustic wave resonator. The acoustic wave resonator includes a multi-layer piezoelectric substrate (MPS). The multi-layer piezoelectric substrate includes a base layer, an intermediate layer and a piezoelectric layer. The intermediate layer is disposed on the base layer. The piezoelectric layer is disposed on the intermediate layer. The acoustic wave resonator also includes a plurality of interdigital transducer electrodes in electrical communication with the piezoelectric layer.

In some aspects, the techniques described herein relate to an acoustic wave resonator including: a multi-layer piezoelectric substrate, the multi-layer piezoelectric substrate including a base layer, an intermediate layer, and a piezoelectric layer, the intermediate layer positioned between the base layer and the piezoelectric layer, the piezoelectric layer including lithium niobate (LiNbO3) having a cut angle in a range from 20 degrees to 40 degrees; and a plurality of interdigital transducer electrodes in electrical communication with the piezoelectric layer.

In some aspects, the techniques described herein relate to an acoustic wave resonator wherein the piezoelectric layer includes 30 degrees Y-cut X-propagation lithium niobate (LiNbO3).

In some aspects, the techniques described herein relate to an acoustic wave resonator wherein a thickness of the intermediate layer is greater than a thickness of the piezoelectric layer.

In some aspects, the techniques described herein relate to an acoustic wave resonator wherein the piezoelectric layer has a thickness in a range from 0.02 L to 0.38 L, L being a wavelength of a main acoustic wave excited by the acoustic wave resonator.

In some aspects, the techniques described herein relate to an acoustic wave resonator wherein the intermediate layer includes silicon dioxide (SiO2).

In some aspects, the techniques described herein relate to an acoustic wave resonator wherein the intermediate layer has a thickness in a range from 0.2 L to 0.6 L, L being a wavelength of a main acoustic wave excited by the acoustic wave resonator.

In some aspects, the techniques described herein relate to an acoustic wave resonator wherein the plurality of interdigital transducer electrodes have a thickness in a range from 0.04 L to 0.16 L, L being a wavelength of a main acoustic wave excited by the acoustic wave resonator.

In some aspects, the techniques described herein relate to an acoustic wave resonator wherein tip areas of electrode fingers of the plurality of interdigital transducer electrodes have a greater thickness than a central area of the electrode fingers of the plurality of interdigital transducer electrodes.

In some aspects, the techniques described herein relate to an acoustic wave resonator wherein tip areas of electrode fingers of the plurality of interdigital transducer electrodes have a greater length than a central area of the electrode fingers of the plurality of interdigital transducer electrodes.

In some aspects, the techniques described herein relate to an acoustic wave resonator wherein the plurality of interdigital transducer electrodes include aluminum (Al), copper (Cu), molybdenum (Mo), tungsten (W), platinum (Pt), or titanium (Ti).

In some aspects, the techniques described herein relate to an acoustic wave resonator wherein the plurality of interdigital transducer electrodes include two layers, one layer includes aluminum and the other layer includes molybdenum.

In some aspects, the techniques described herein relate to an acoustic wave resonator wherein the plurality of interdigital transducer electrodes include a bus bar.

In some aspects, the techniques described herein relate to an acoustic wave resonator further including a partial bottom silicon dioxide (SiO2) layer partially disposed between the multi-layer piezoelectric substrate and the plurality of interdigital transducer electrodes.

In some aspects, the techniques described herein relate to an acoustic wave resonator further including a silicon nitride (SiN) layer disposed on a central area of electrode fingers of the plurality of interdigital transducer electrodes and on an end region of the plurality of interdigital transducer electrodes.

In some aspects, the techniques described herein relate to an acoustic wave resonator further including a silicon dioxide (SiO2) layer disposed on a tip area of electrode fingers of the plurality of interdigital transducer electrodes.

In some aspects, the techniques described herein relate to an acoustic wave resonator wherein the base layer includes silicon (Si), silicon carbide (SiC), quartz (Qz), Poly-Si/Si compound, a-Si/Si compound, or silicon nitride (SiN/Si) compound.

In some aspects, the techniques described herein relate to an acoustic wave resonator wherein the multi-layer piezoelectric substrate consists of the base layer, the intermediate layer, and the piezoelectric layer.

In some aspects, the techniques described herein relate to a radio frequency module including an acoustic wave resonator, the acoustic wave resonator including: a multi-layer piezoelectric substrate, the multi-layer piezoelectric substrate including a base layer, an intermediate layer, and a piezoelectric layer disposed on the intermediate layer, the intermediate layer positioned between the base layer and the piezoelectric layer, the piezoelectric layer including lithium niobate (LiNbO3) having a cut angle in a range from 20 degrees to 40 degrees; and a plurality of interdigital transducer electrodes in electrical communication with the piezoelectric layer.

In some aspects, the techniques described herein relate to a radio frequency module wherein the radio frequency module is configured as a front end module.

In some aspects, the techniques described herein relate to a radio frequency module wherein the acoustic wave resonator is configured as a surface acoustic wave resonator.

In some aspects, the techniques described herein relate to a wireless communication device including: a radio frequency module including an acoustic wave resonator, the acoustic wave resonator including: a multi-layer piezoelectric substrate including a base layer, an intermediate layer, and a piezoelectric layer disposed on the intermediate layer, the intermediate layer positioned between the base layer and the piezoelectric layer, the piezoelectric layer including lithium niobate (LiNbO3) having a cut angle in a range from 20 degrees to 40 degrees; and a plurality of interdigital transducer electrodes in electrical communication with the piezoelectric layer.

For purposes of summarizing the disclosure, certain aspects, advantages and novel features of the innovations have been described herein. It is to be understood that not necessarily all such advantages may be achieved in accordance with any particular embodiment. Thus, the innovations may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1A is a simplified plan view of a surface acoustic wave resonator according to an embodiment.

FIG. 1B is a simplified plan view of a surface acoustic wave resonator according to another embodiment.

FIG. 1C is a simplified plan view of a surface acoustic wave resonator according to another embodiment.

FIG. 2A is a top view of a surface acoustic wave resonator according to an embodiment.

FIG. 2B is a cross-sectional front view of the surface acoustic wave resonator of FIG. 2A.

FIG. 2C is a cross-sectional side view of the surface acoustic wave resonator of FIGS. 2A, 2B.

FIG. 3 illustrates changes in the temperature coefficient of frequency (TCFs and TCFp), in the electromechanical coupling coefficient (k2), and in the resonant frequency (fs) of a surface acoustic wave resonator according to an embodiment with changes in thickness of the intermediate layer.

FIG. 4 illustrates changes in the electromechanical coupling coefficient (k2) of a surface acoustic wave resonator according to an embodiment with changes in cut angle of the piezoelectric layer.

FIG. 5A illustrates changes in the electromechanical coupling coefficient (k2), and in the acoustic wave velocity of a surface acoustic wave resonator according to an embodiment with changes in thickness of the plurality of the interdigital transducer electrodes (IDT).

FIG. 5B is a cross-sectional side view of a surface acoustic wave resonator according to an embodiment the plurality of the interdigital transducer electrodes having at least two layers.

FIG. 5C illustrates changes in the electromechanical coupling coefficient (k2), and in the acoustic wave velocity of the surface acoustic wave resonator according to FIG. 5B with changes in thickness of the molybdenum layer of the plurality of the interdigital transducer electrodes (IDT).

FIG. 6A is a top view of a surface acoustic wave resonator according to an embodiment including thicker IDT finger tips.

FIG. 6B is a cross-sectional front view of the surface acoustic wave resonator of FIG. 6A.

FIG. 7 is a graph showing simulated frequency responses of the surface acoustic wave resonator of FIGS. 6A and 6B compared to the surface acoustic wave resonator of FIGS. 2A, 2B, 2C.

FIG. 8 is a graph showing simulated frequency responses of the surface acoustic wave resonator of FIGS. 6A and 6B at two different widths.

FIG. 9A is a top view of a surface acoustic wave resonator according to an embodiment including thicker IDT finger tips in combination with a bus bar.

FIG. 9B is a cross-sectional front view of the surface acoustic wave resonator of FIG. 9A.

FIG. 10A is a top view of a surface acoustic wave resonator according to an embodiment including a partial bottom silicon dioxide layer.

FIG. 10B is a cross-sectional front view of the surface acoustic wave resonator of FIG. 10A.

FIG. 11 is a graph showing simulated frequency responses of the surface acoustic wave resonator of FIGS. 10A and 10B compared to the surface acoustic wave resonator of FIGS. 6A and 6B.

FIG. 12A is a top view of a surface acoustic wave resonator according to an embodiment including longer IDT finger tips.

FIG. 12B is a cross-sectional front view of the surface acoustic wave resonator of FIG. 12A.

FIG. 13A is a top view of a surface acoustic wave resonator according to an embodiment including a silicon nitride layer.

FIG. 13B is a cross-sectional front view of the surface acoustic wave resonator of FIG. 13A.

FIG. 13C is a top view with corresponding cross-sectional views of a surface acoustic wave (SAW) resonator according to another embodiment including a silicon nitride layer.

FIG. 14A is a top view of a surface acoustic wave resonator according to an embodiment including a silicon dioxide layer.

FIG. 14B is a cross-sectional front view of the surface acoustic wave resonator of FIG. 14A.

FIG. 15 is a combination of the surface acoustic wave resonator of FIGS. 12A, 12B with the surface acoustic wave resonator of FIGS. 10A and 10B.

FIG. 16 is a combination of the surface acoustic wave resonator of FIGS. 13A, 13B with the surface acoustic wave resonator of FIGS. 10A and 10B.

FIG. 17 is a combination of the surface acoustic wave resonator of FIGS. 14A, 14B with the surface acoustic wave resonator of FIGS. 10A and 10B.

FIG. 18 is a block diagram of one example of a filter module that can include one or more acoustic wave elements according to an embodiment.

FIG. 19 is a block diagram of one example of a front-end module that can include one or more filter modules according to an embodiment.

FIG. 20 is a block diagram of a wireless device according to an embodiment including the front-end module of FIG. 19.

### DETAILED DESCRIPTION OF EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with surface acoustic wave (SAW) devices. SAW devices include SAW resonators, SAW delay lines, and multi-mode SAW (MMS) filters (e.g., double mode SAW (DMS) filters). Any features of the SAW resonators and/or devices discussed herein can be implemented in any suitable SAW device.

In general, high quality factor (Q), large effective electromechanical coupling coefficient (k2), high frequency ability, and spurious free response can be significant aspects for acoustic wave elements to enable low-loss filters, delay lines, stable oscillators, and sensitive sensors.

Multi-layer piezoelectric substrate (MPS) acoustic wave devices can thermally insulate an interdigital transducer electrode and a piezoelectric layer. By reducing dissipative thermal impedance of the acoustic wave device, the ruggedness and power handling can be improved. Furthermore, MPS acoustic wave devices can include a high power durability filter solution.

Some MPS acoustic wave devices have achieved a packaging structure with copper (Cu) based chip-scale packages (CSP) in combination with a silicon (Si) substrate. However, such approaches have encountered technical challenges related to thermal distortion of the substrate and the CSP.

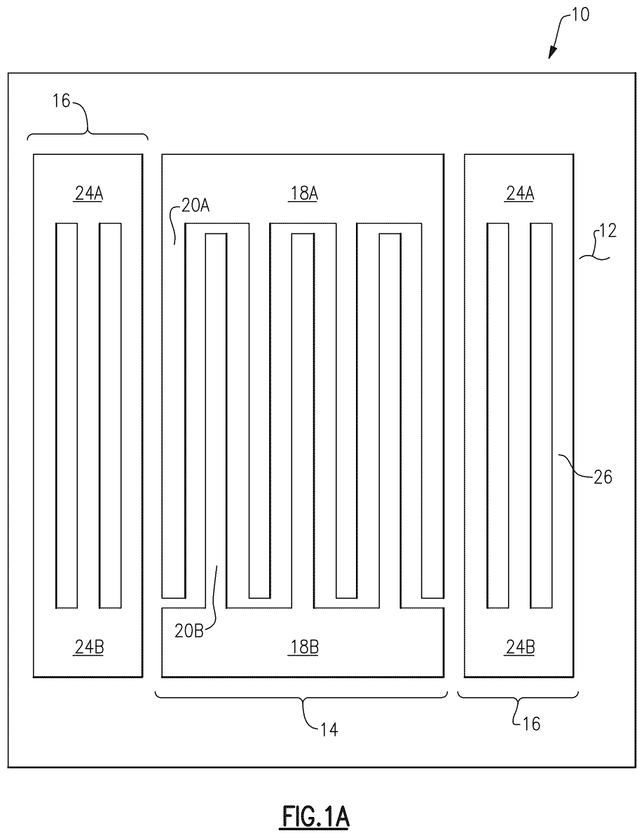

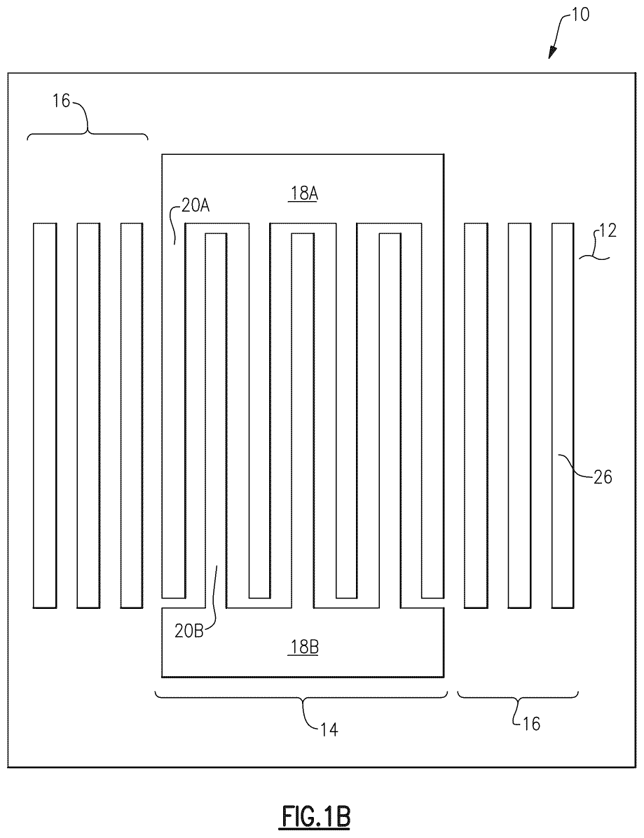

FIG. 1 illustrates a plan view of a surface acoustic wave (SAW) resonator 10 such as might be used in a SAW filter, duplexer, balun, etc.

Acoustic wave resonator 10 can include an interdigital transducer (IDT) electrodes 14 in electrical communication with a piezoelectric substrate 12, for example, a lithium tantalate (LiTaO3) or lithium niobate (LiNbO3) substrate, and reflector electrodes 16. In use, the IDT electrodes 14 excite a main acoustic wave having a wavelength L (or: λ) along a surface of the piezoelectric substrate 12. The reflector electrodes 16 sandwich the IDT electrodes 14 and reflect the main acoustic wave back and forth through the IDT electrodes 14. The IDT electrodes 14 can be positioned between the reflector electrode 16 in a wave propagation direction. The main acoustic wave of the device travels perpendicular to the lengthwise direction of the IDT electrodes 14.

The IDT electrodes 14 include a first bus bar electrode 18A and a second bus bar electrode 18B facing first bus bar electrode 18A. The bus bar electrodes 18A, 18B may be referred to herein and labelled in the figures as bus bar electrode 18. The IDT electrodes 14 further include first electrode fingers 20A extending from the first bus bar electrode 18A toward the second bus bar electrode 18B, and second electrode fingers 20B extending from the second bus bar electrode 18B toward the first bus bar electrode 18A.

The reflector electrodes 16 (also referred to as reflector gratings) each include a first reflector bus bar electrode 24A and a second reflector bus bar electrode 24B (collectively referred to herein as reflector bus bar electrode 24) and reflector fingers 26 extending between and electrically coupling the first bus bar electrode 24A and the second bus bar electrode 24B.

In other embodiments disclosed herein, as illustrated in FIG. 1B, the reflector bus bar electrodes 24A, 24B may be omitted and the reflector fingers 26 may be electrically unconnected with each other. Further, as illustrated in FIG. 1C, acoustic wave resonators as disclosed herein may include dummy electrode fingers 20C in a gap region between a bus bar (e.g., the first bus bar electrode 18A or the second bus bar electrode 18B) and fingers (e.g., the second electrode fingers 20B or the first electrode fingers 20A) extending from the other bus bar that are aligned with respective electrode fingers 20A, 20B. Each dummy electrode finger 20C extends from the opposite bus bar electrode 18A, 18B than the respective electrode finger 20A, 20B with which it is aligned. The dummy electrode finger 20C can function as pseudo-electrodes for mitigating or preventing interference with the propagation of a wave generated by the fingers of an IDT electrode.

It should be appreciated that the acoustic wave resonators 10 illustrated in FIGS. 1A-1C, as well as the other circuit elements illustrated in other figures presented herein, are illustrated in a highly simplified form. The relative dimensions of the different features are not shown to scale. Further, typical acoustic wave resonators would commonly include a far greater number of electrode fingers and reflector fingers than illustrated. Typical acoustic wave resonators or filter elements may also include multiple IDT electrodes sandwiched between the reflector electrodes.

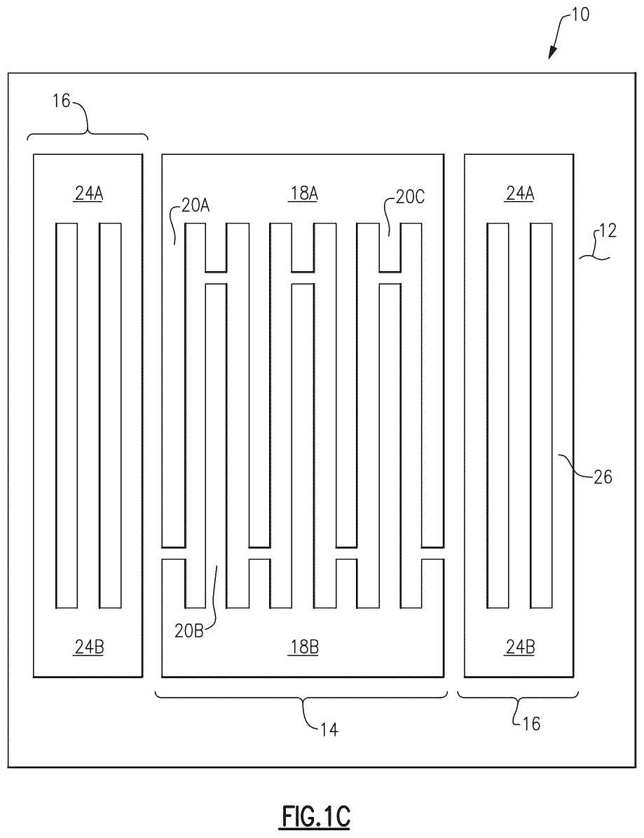

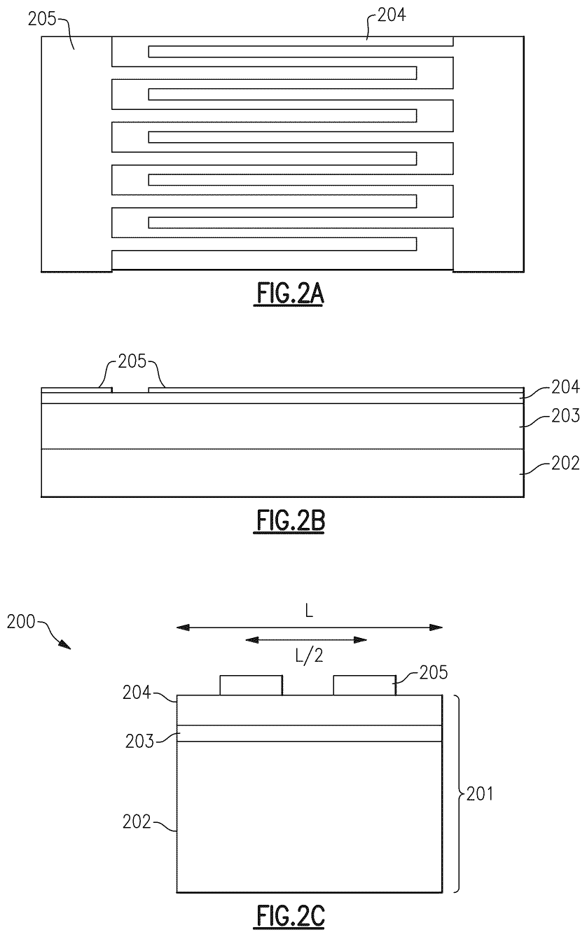

FIGS. 2A, 2B, and 2C show a surface acoustic wave resonator 200 according to an embodiment. In particular, FIG. 2A illustrates a top view of the surface acoustic wave resonator 200. FIG. 2B illustrates a cross-sectional front view of the surface acoustic wave resonator 200 of FIG. 2A. FIG. 2C illustrates a cross-sectional side view of a portion of the surface acoustic wave resonator 200 of FIGS. 2A and 2B. The surface acoustic wave (SAW) resonator 200 as illustrated in FIGS. 2A, 2B, and 2C can be referred to as a basic structure of the acoustic wave resonator 200 according to an embodiment.

The SAW resonator 200 includes a multi-layer piezoelectric substrate (MPS) 201. The multi-layer piezoelectric substrate 201 includes a base layer 202, an intermediate layer 203 and a piezoelectric layer 204. The intermediate layer 203 is disposed on the base layer 202. The piezoelectric layer 204 is disposed on the intermediate layer 203. The SAW resonator 200 includes a plurality of interdigital transducer electrodes 205 in electrical communication with the piezoelectric layer 204. The interdigital transducer electrodes 205 can be formed with (e.g., disposed on, in, or partially in) the piezoelectric layer 204.

In the embodiment of FIGS. 2A, 2B, and 2C, the piezoelectric layer 204 is made of lithium niobate (LiNbO3). Lithium niobate can provide a thinner layer than the typically used silicon for the piezoelectric layer 204. However, the piezoelectric layer 204 is not limited to lithium niobate, it can also be made of lithium tantalate or other piezoelectric or dielectric materials. Optionally, the piezoelectric layer can have a crystal orientation, for example, rotated 30 degree Y-cut X-propagation LiNbO3. Rotated angle can be ranged from 20 to 40 degree. Thus, a higher k2 can be provided when the piezoelectric layer 204 is based on lithium niobate. In particular, k2 can have a value of more than 22% or of 25%.

The piezoelectric layer 204 can have a thickness in a range from 0.02 L to 0.38 L. In particular, the piezoelectric layer 204 can have a thickness in a range from 0.05 L to 0.3 L. L (or: lambda) is the wavelength of the main acoustic wave excited by the SAW resonator 200. That means the dimensions of the layer structure of the MPS depends at least in part on the wavelength L of the main acoustic wave. The wavelength L as well as L/2 is exemplarily shown in FIG. 2C in relation to two interdigital transducer electrodes 205.

The intermediate layer 203 can be made of silicon dioxide (SiO2) or a similar compound. The intermediate layer 203 can have a thickness in a range from 0.2 L to 0.6 L. In particular, the intermediate layer 203 has a thickness in a range from 0.3 L to 0.5 L.

The plurality of interdigital transducer electrodes 205 can be selected from or consist of the group of: aluminum (Al), copper (Cu), molybdenum (Mo), tungsten (W), platinum (Pt), and titanium (Ti). The interdigital transducer electrodes 205 may include alloys, such as AlMgCu, AlCu, etc. In some embodiments, interdigital transducer electrodes 205 can have a multi-layer structure having two or more layers of different materials.

The base layer 202 can be selected from or consists of the group of: silicon (Si), silicon carbide (SiC), quartz (Qz), Poly-Si/Si, a-Si/Si, and silicon nitride (SiN/Si). A preferred combination of materials is aluminum for the plurality of interdigital transducer electrodes 205 and Si or Qz for the base layer 202. The MPS 201 can further combine the SiO2 based intermediate layer 203 and the LiNbO3 based piezoelectric layer 204 to the Si or Qz based base layer 202. The base layer 202 can be any suitable substrate layer, such as a silicon layer, a quartz layer, a ceramic layer, a glass layer, a spinel layer, a magnesium oxide spinel layer, a sapphire layer, a diamond layer, a silicon carbide layer, a silicon nitride layer, an aluminum nitride layer, or the like. The base layer 202 can have a relatively high acoustic impedance. An acoustic impedance of the base layer 202 can be higher than an acoustic impedance of the piezoelectric layer 204. For instance, the base layer 202 can have a higher acoustic impedance than an acoustic impedance of lithium niobate and a higher acoustic impedance than lithium tantalate. The acoustic impedance of the base layer 202 can be higher than an acoustic impedance of silicon dioxide (SiO₂). The SAW resonator 200 including the piezoelectric layer 204 on a base layer 202 with relatively high thermal conductivity, such as silicon substrate, can achieve better thermal dissipation compared to a similar SAW resonator without the high impedance base layer 202.

In some embodiments, the multi-layer piezoelectric substrate 201 can consist of the base layer 202, the intermediate layer 203, and the piezoelectric layer 204. That means the acoustic wave resonator 200 can be configured without any coating (such as a top SiO2 over coat) over the plurality of interdigital transducer electrodes 205, for example. Thus, a higher k2 can be provided. Furthermore, a good TCF can be provided. In some embodiments, the temperature coefficient of resonant frequency (TCFs) can be negative and the temperature coefficient of anti-resonant frequency (TCFp) can be positive in the acoustic wave resonator 200.

Advantageously, the SAW resonator 200 has a wider filter passband, under high temperature conditions. This results in improved FE process step during manufacturing of the SAW resonator 200. Furthermore, such a self-protecting feature is beneficial for power handling.

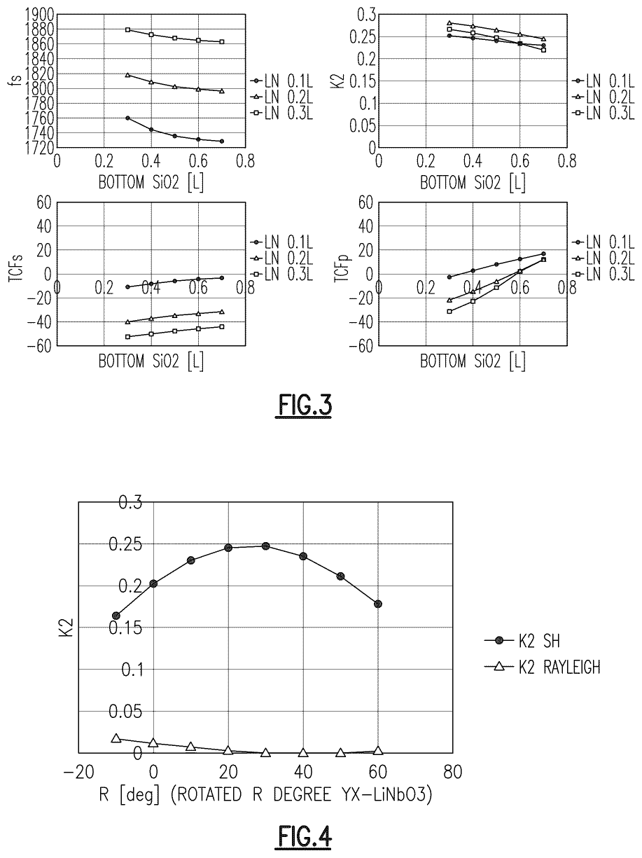

FIG. 3 illustrates changes in the temperature coefficient of frequency (TCFs and TCFp), in the electromechanical coupling coefficient (k2), and in the resonant frequency (fs) of a surface acoustic wave (SAW) resonator according to an embodiment with changes in thickness of the intermediate layer 203. TCFs is the temperature coefficient of resonant frequency and TCFp is the temperature coefficient of anti-resonant frequency.

The plots shown in FIG. 3 are based on a 2D simulation of a SAW resonator including a silicon base layer, a silicon dioxide intermediate layer, a 30 degree rotated lithium niobate (30 LN) piezoelectric layer, and an aluminum plurality of interdigital transducer electrodes having a thickness of 0.08 L. Such a SAW resonator can basically include the same features as the SAW resonator 200 of FIGS. 2A, 2B, and 2C. In the four plots of FIG. 3, the 30 LN piezoelectric layer has an exemplary thickness of 0.1 L, 0.2 L, and 0.3 L which are compared to one another. It can be seen that TCFs, TCFp, k2 and fs improve the thinner the 30 LN piezoelectric layer is formed.

Advantageously, a SAW resonator having a negative TCFs in combination with a positive TCFp provides a wider passband in high temperature. This is beneficial for durability under high power injection.

FIG. 4 illustrates changes in the electromechanical coupling coefficient (k2) of a surface acoustic wave resonator according to an embodiment with changes in cut angle of the piezoelectric layer. Such a SAW resonator can basically include the same features as the SAW resonator 200 of FIGS. 2A, 2B, and 2C.

The plot shown in FIG. 4 is based on a 2D simulation of a SAW resonator including a silicon base layer, a silicon dioxide intermediate layer having a thickness of 0.3 L, a lithium niobate (LN) piezoelectric layer having a thickness of 0.3 L, and a plurality of aluminum interdigital transducer electrodes having a thickness of 0.08 L. The plot shows changes in k2 when varying the cut angle of the LN layer from −10 degrees to +60 degrees in steps of 10 degrees.

A cut angle of the LN between 20 degrees and 40 degrees can provide a larger k2 on shear horizontal (SH) mode. Furthermore, the cut angle of the LN between 20 degrees and 60 degrees can provide a smaller k2 on Rayleigh mode. Hence, the SAW resonator as described above can reduce spurious signals appearing in the frequency response of the SAW resonator.

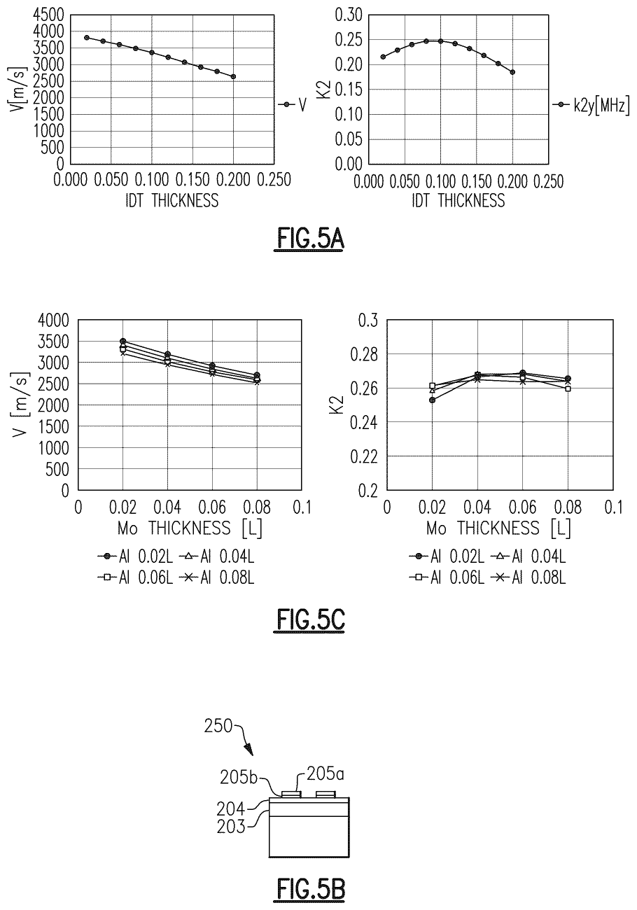

FIG. 5A illustrates changes in the electromechanical coupling coefficient (k2), and in the acoustic wave velocity of a SAW resonator according to an embodiment with changes in thickness of the plurality of the interdigital transducer (IDT) electrodes. Such a SAW resonator can be configured as the SAW resonator of FIG. 4 with a 30 degree rotated LN layer. In difference to the SAW resonator of FIG. 4, the plurality of interdigital transducer electrodes of the SAW resonator of FIG. 5A is not limited to a thickness of 0.3 L. The plurality of interdigital transducer electrodes of the SAW resonator used in the simulation of FIG. 5A have an exemplary thickness in a range from 0.02 L to 0.20 L in steps of 0.02 L. L is the wavelength of the main acoustic wave excited by the SAW resonator.

FIG. 5A indicates that a thicker aluminum IDT provides a lower acoustic wave velocity of the SAW resonator. Advantageously, the SAW resonator having a thickness of the IDT electrodes in a range from 0.06 L to 0.14 L provides a peak in k2 at a value about 0.25 corresponding to 25% (cf. the right plot of FIG. 5A).

FIG. 5B is a cross-sectional side view of a SAW resonator 250 according to an embodiment the plurality of the interdigital transducer electrodes 205 having a multilayer-structure including two or more layers 205a, 205b. Besides that, the SAW resonator 250 is similar to the SAW resonator of FIG. 5A. The SAW resonator 250 can further include a piezoelectric layer 204 having a thickness of 0.3 L and supporting the plurality of the interdigital transducer electrodes 205. The SAW resonator 250 can further include an intermediate layer 203 having a thickness of 0.3 L and supporting the piezoelectric layer 204.

In some embodiments, one layer 205a of the at least two layers can include aluminum, and the other layer 205b can include molybdenum, for example. The layer 205a can be the top layer of the plurality of the interdigital transducer electrodes 205, the layer 205b can be the bottom layer of the plurality of the interdigital transducer electrodes 205. In some embodiments, the layer 205b can be in contact with the piezoelectric layer 204.

FIG. 5C illustrates changes in the electromechanical coupling coefficient (k2), and in the acoustic wave velocity of the surface acoustic wave resonator 250 according to FIG. 5B with changes in thickness of the molybdenum layer 205b of the plurality of the interdigital transducer (IDT) electrodes.

The plots shown in FIG. 5C are based on a 2D simulation of the SAW resonator 250. In this example, a combination of the aluminum layer 205a and the molybdenum layer 205b is presented, but not limited to such a material combination. Advantageously, the plurality of the interdigital transducer (IDT) electrodes 205 having at least two layers, also called stacked IDT, provide more freedom in tuning the acoustic wave velocity.

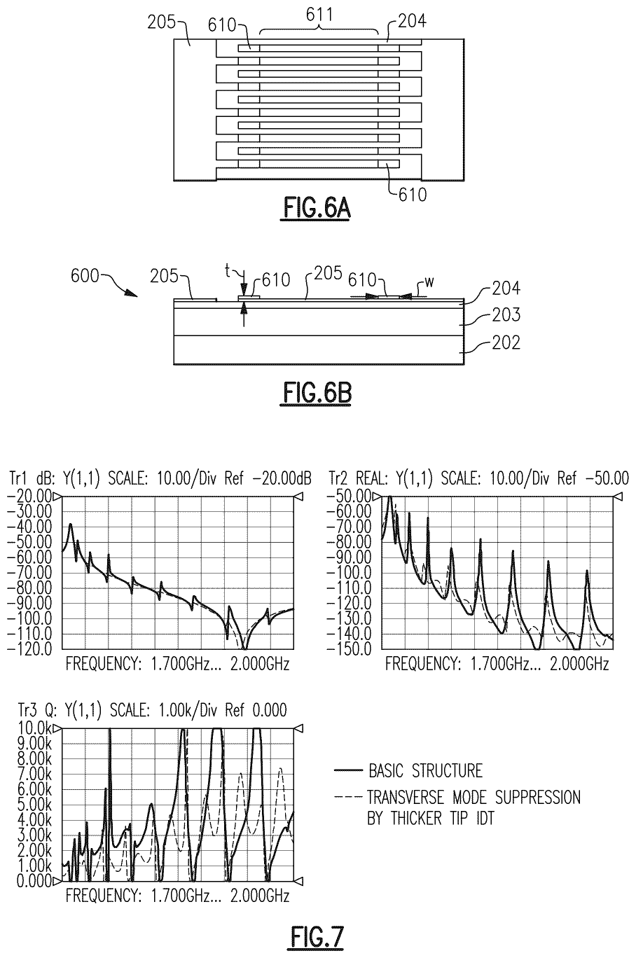

FIGS. 6A and 6B illustrate a SAW resonator 600 according to an embodiment including thicker IDT finger tips at tip areas 610. In particular, FIG. 6A is a top view of the SAW resonator 600. FIG. 6B is a cross-sectional front view of the surface acoustic wave resonator 600 of FIG. 6A. FIG. 6B also shows the definition of the thickness t and of the width w, as reference to in the present disclosure.

That means the tip areas 610 of electrode fingers of the plurality of interdigital transducer electrodes 205 can have a greater thickness than a central area 611 of the electrode fingers of the plurality of interdigital transducer electrodes 205. The tip areas 610 may include the open end of the IDT finger and the connected end of the IDT finger on the other side of the central area 611.

Hence, transverse mode suppression can be improved by providing thicker IDT finger tips at the tip areas 610.

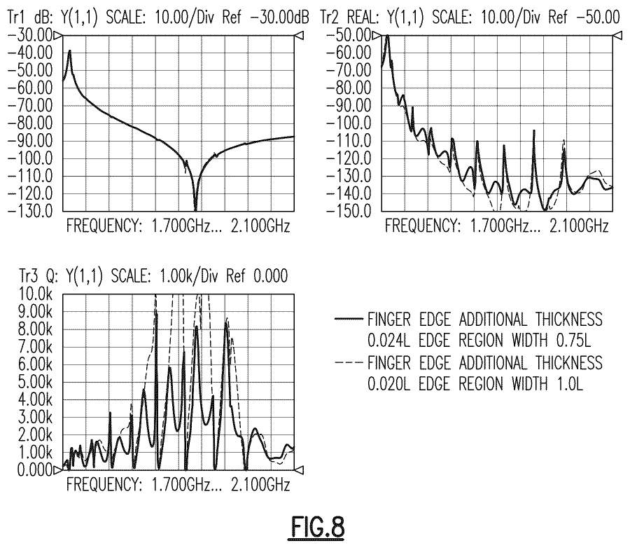

FIG. 7 is a graph showing simulated frequency responses of the surface acoustic wave resonator 600 of FIGS. 6A and 6B compared to the surface acoustic wave resonator 200 of FIGS. 2A, 2B, and 2C which may be called the “basic structure”. The plots shown in FIG. 7 are based on a 3D simulation of the SAW resonator 600, 200.

As can be seen in the plots of FIG. 7, transverse mode suppression can be improved in relation to the transverse mode suppression of the SAW resonator 200 by providing thicker IDT finger tips at the tip areas 610.

FIG. 8 is a graph showing simulated frequency responses of the surface acoustic wave resonator 600 of FIGS. 6A and 6B at two different widths.

In a first example, the tip areas 610 of the IDT fingers have an additional thickness of 0.024 L in relation to the central area 611 of the IDT fingers. Additionally, the tip areas 610 of the IDT fingers have a width of 0.75 L.

In a second example, the tip areas 610 of the IDT fingers have an additional thickness of 0.020 L in relation to the central area 611 of the IDT fingers. Additionally, the tip areas 610 of the IDT fingers have a width of 1.0 L. Advantageously, Q can be improved when forming IDT fingertip areas 610 with a width of 1.0 L.

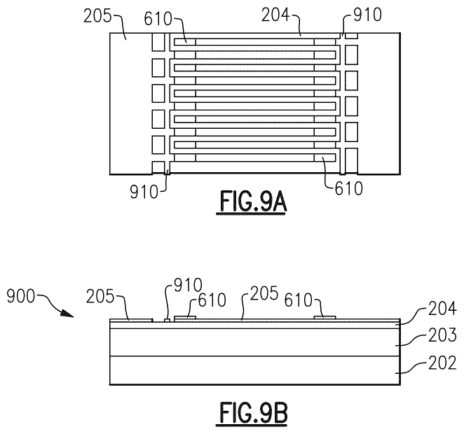

FIGS. 9A and 9B illustrate a SAW resonator 900 according to an embodiment including thicker IDT finger tips at the tip areas 610 in combination with a bus bar 910. Thereby, FIG. 9A is a top view of the surface acoustic wave resonator 900. FIG. 9B is a cross-sectional front view of the surface acoustic wave resonator 900 of FIG. 9A. Exemplarily, the plurality of interdigital transducer electrodes 205 can include a bus bar 910.

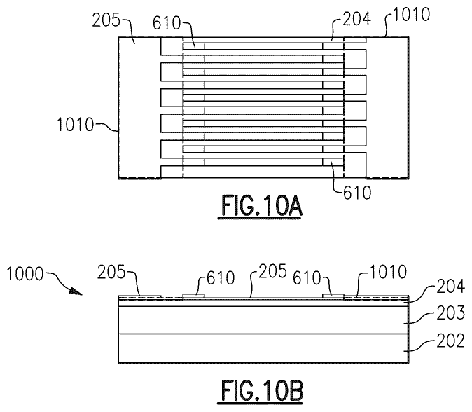

FIGS. 10A and 10B illustrate a SAW resonator 1000 according to an embodiment including a partial bottom silicon dioxide layer 1010. FIG. 10A is a top view of the surface acoustic wave resonator 1000. FIG. 10B is a cross-sectional front view of the surface acoustic wave resonator 1000 of FIG. 10A. Exemplarily, the SAW resonator 1000 can further include a partial bottom silicon dioxide (SiO2) layer 1010 partially disposed between the MPS 201 and the plurality of interdigital transducer electrodes 205.

In some embodiments, the SAW resonator 1000 further includes the tip areas 610 of the IDT fingers having an additional thickness.

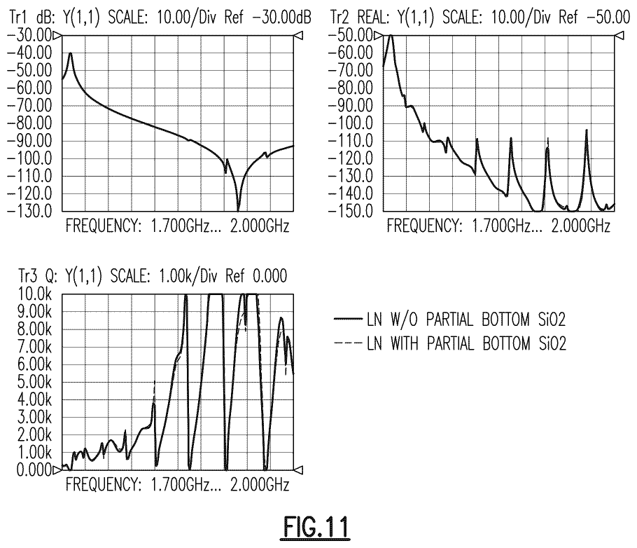

FIG. 11 is a graph showing simulated frequency responses of the surface acoustic wave resonator 1000 of FIGS. 10A and 10B compared to the surface acoustic wave resonator 600 of FIGS. 6A and 6B. That means, both SAW resonators 600 and 1000 have thicker IDT finger tips at the tip areas 610, with the SAW resonator 1000 additionally including the partial bottom silicon dioxide layer 1010.

The plots shown in FIG. 11 are based on a 3D simulation of the SAW resonator 600, 1000 both including a silicon base layer, a silicon dioxide intermediate layer having a thickness of 0.4 L, a 30 degree rotated lithium niobate (30 LN) piezoelectric layer having a thickness of 0.1 L, and an aluminum plurality of interdigital transducer electrodes having a thickness of 0.08 L. It can be seen that Q can be improved when providing the partial bottom silicon dioxide layer 1010.

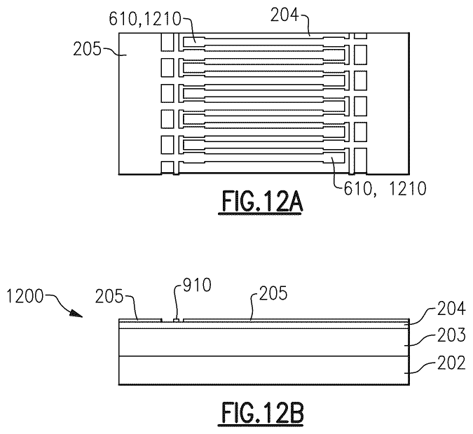

FIGS. 12A and 12B illustrate a SAW resonator 1200 according to an embodiment including longer IDT finger tips at tip areas 1210. FIG. 12A is a top view of the surface acoustic wave resonator 1200. FIG. 12B is a cross-sectional front view of the surface acoustic wave resonator 1200 of FIG. 12A. Tip areas 610, 1210 of electrode fingers of the plurality of interdigital transducer electrodes 205 can have a greater length than a central area 611 of the electrode fingers of the plurality of interdigital transducer electrodes 205.

Optionally, the SAW resonator 1200 can further include the bus bar 910.

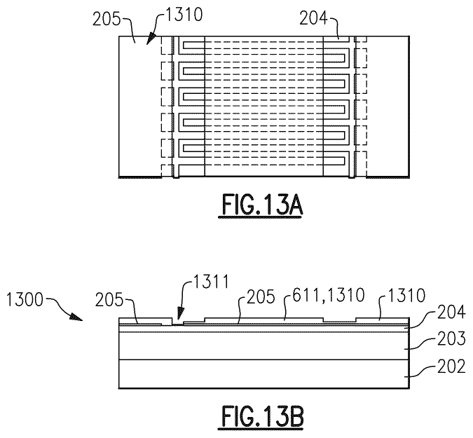

FIGS. 13A and 13B illustrate a surface acoustic wave (SAW) resonator 1300 according to an embodiment including a silicon nitride layer 1310. FIG. 13A is a top view of the SAW resonator 1300 and FIG. 13B is a cross-sectional front view of the surface acoustic wave resonator 1300 of FIG. 13A.

The SAW resonator 1300 can include a silicon nitride (SiN) layer 1310 partially coating the plurality of interdigital transducer electrodes 205. The silicon nitride (SiN) layer 1310 can be disposed on a central area 611 of the electrode fingers of the plurality of interdigital transducer electrodes 205 and on an end region of the plurality of interdigital transducer electrodes 205. The SiN layer 1310 can be configured or form a so called SiN trench structure. The SiN layer 1310 may be designed as a high speed layer.

FIG. 13C illustrates a surface acoustic wave (SAW) resonator 1300 according to another embodiment including a silicon nitride layer 1310. FIG. 13C shows a top view of the SAW resonator 1300 and two cross-sectional front views A-A, B-B of the surface acoustic wave resonator 1300 and two cross-sectional side views C-C, D-D of the surface acoustic wave resonator 1300.

The SAW resonator 1300 can include a silicon nitride (SiN) layer 1310 partially coating the plurality of interdigital transducer electrodes 205. The silicon nitride (SiN) layer 1310 can be disposed on a central area 611 of the electrode fingers of the plurality of interdigital transducer electrodes 205 and on an end region of the plurality of interdigital transducer electrodes 205. Furthermore, the SAW resonator 1300 can include a trench 1311, as illustrated in particular in the cross-sectional views B-B and D-D. Such a configuration can be called a SiN trench structure or an edge region piezo etching structure. Advantageously, such a structure of the SAW resonator 1300 can slow down acoustic wave velocity of the end region compared to the central area. By using this configuration, transverse mode can be suppressed. Further, the SiN layer 1310 may be designed as a high speed layer.

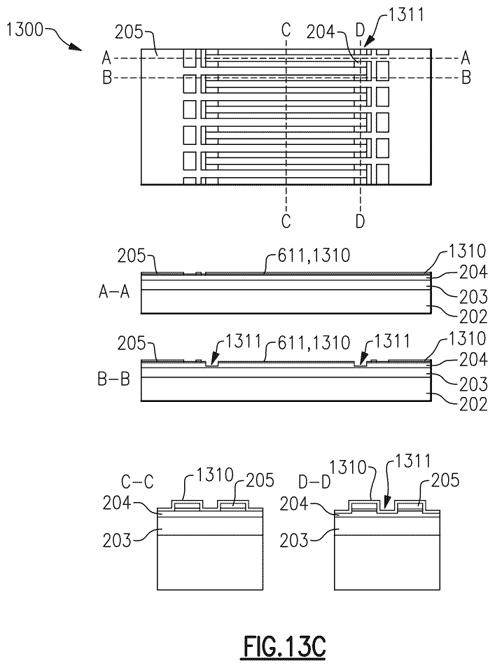

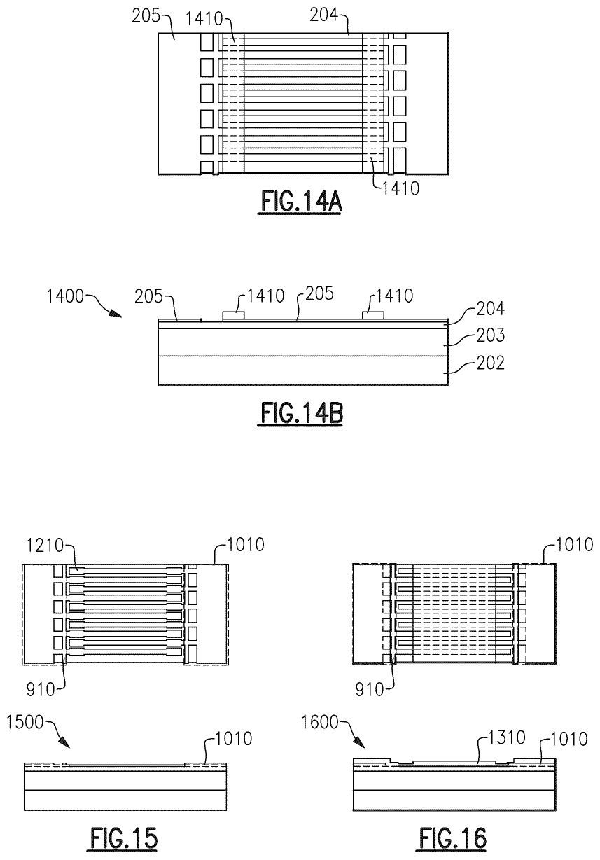

FIGS. 14A and 14B illustrate a surface acoustic wave (SAW) resonator 1400 according to an embodiment including a silicon dioxide layer 1410. FIG. 14A is a top view of the SAW resonator 1400. FIG. 14B is a cross-sectional front view of the surface acoustic wave resonator 1400 of FIG. 14A.

The SAW resonator 1400 can include a silicon dioxide (SiO2) layer 1410 partially coating the plurality of interdigital transducer electrodes 205. The silicon dioxide (SiO2) layer 1410 can be disposed on a tip area 610 of the electrode fingers of the plurality of interdigital transducer electrodes 205. The SiO2 layer 1410 can be configured or form a so-called SiO2 frame structure. The SiO2 layer 1410 may be designed as a low speed layer.

FIG. 15 is a combination of the surface acoustic wave resonator 1200 of FIGS. 12A and 12B with the surface acoustic wave resonator 1000 of FIGS. 10A, 10B. Such a SAW resonator 1500 exemplarily includes IDT finger tips 1210 with greater length. Furthermore, such a SAW resonator 1500 includes a partial bottom silicon dioxide layer 1010 and a bus bar 910.

FIG. 16 is a combination of the surface acoustic wave resonator 1300 of FIGS. 13A and 13B with the surface acoustic wave resonator 1000 of FIGS. 10A and 10B. Such a SAW resonator 1600 exemplarily includes a SiN layer 1310 disposed on a central area 611 of the electrode fingers of the plurality of interdigital transducer electrodes 205 and on an end region of the plurality of interdigital transducer electrodes 205. Furthermore, such a SAW resonator 1600 includes a partial bottom silicon dioxide layer 1010 and a bus bar 910.

FIG. 17 is a combination of the surface acoustic wave resonator 1400 of FIGS. 14A and 14B with the surface acoustic wave resonator 1000 of FIGS. 10A, 10B. Such a SAW resonator 1700 exemplarily includes a SiO2 layer 1410 disposed on a tip area 610 of the electrode fingers of the plurality of interdigital transducer electrodes 205. Furthermore, such a SAW resonator 1700 includes a partial bottom silicon dioxide layer 1010 and a bus bar 910.

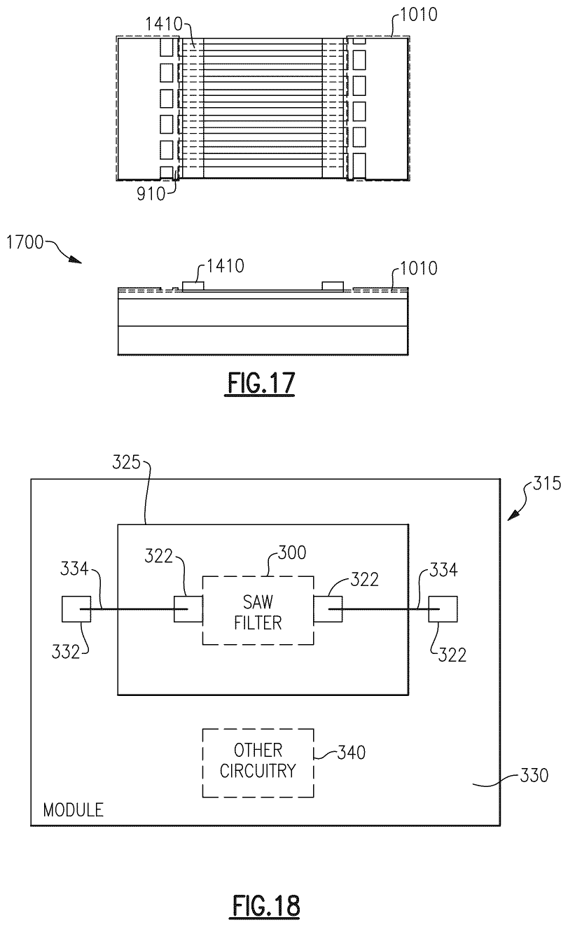

Examples of the SAW devices, e.g., SAW resonators discussed herein can be implemented in a variety of packaged modules. Some example packaged modules will now be discussed in which any suitable principles and advantages of the SAW devices discussed herein can be implemented. FIGS. 18, 19, and 20 are schematic block diagrams of illustrative packaged modules and devices according to certain embodiments.

As discussed above, surface acoustic wave resonators can be used in surface acoustic wave (SAW) RF filters. In turn, a SAW RF filter using one or more surface acoustic wave elements may be incorporated into and packaged as a module that may ultimately be used in an electronic device, such as a wireless communications device, for example. FIG. 18 is a block diagram illustrating one example of a module 315 including a SAW filter 300. The SAW filter 300 may be implemented on one or more die(s) 325 including one or more connection pads 322. For example, the SAW filter 300 may include a connection pad 322 that corresponds to an input contact for the SAW filter and another connection pad 322 that corresponds to an output contact for the SAW filter. The packaged module 315 includes a packaging substrate 330 that is configured to receive a plurality of components, including the die 325. A plurality of connection pads 332 can be disposed on the packaging substrate 330, and the various connection pads 322 of the SAW filter die 325 can be connected to the connection pads 332 on the packaging substrate 330 via electrical connectors 334, which can be solder bumps or wirebonds, for example, to allow for passing of various signals to and from the SAW filter 300. The module 315 may optionally further include other circuitry die 340, for example, one or more additional filter(s), amplifiers, pre-filters, modulators, demodulators, down converters, and the like, as would be known to one of skill in the art of semiconductor fabrication in view of the disclosure herein. In some embodiments, the module 315 can also include one or more packaging structures to, for example, provide protection and facilitate easier handling of the module 315. Such a packaging structure can include an overmold formed over the packaging substrate 330 and dimensioned to substantially encapsulate the various circuits and components thereon.

Various examples and embodiments of the SAW filter 300 can be used in a wide variety of electronic devices. For example, the SAW filter 300 can be used in an antenna duplexer, which itself can be incorporated into a variety of electronic devices, such as RF front-end modules and communication devices.

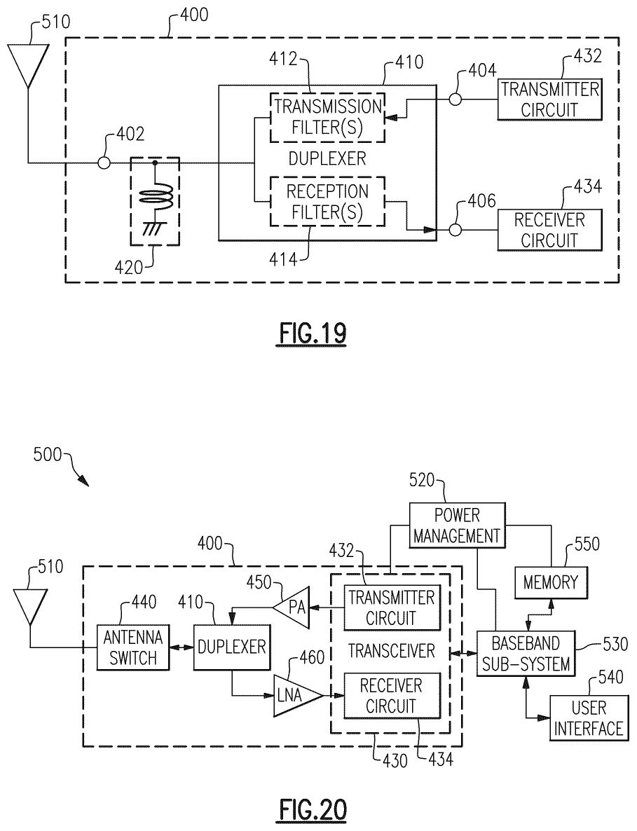

Referring to FIG. 19, there is illustrated a block diagram of one example of a front-end module 400, which may be used in an electronic device such as a wireless communications device (e.g., a mobile phone) for example. The front-end module 400 includes an antenna duplexer 410 having a common node 402, an input node 404, and an output node 406. An antenna 510 is connected to the common node 402.

The antenna duplexer 410 may include one or more transmission filters 412 connected between the input node 404 and the common node 402, and one or more reception filters 414 connected between the common node 402 and the output node 406. The passband(s) of the transmission filter(s) are different from the passband(s) of the reception filters. Examples of the SAW filter 300 can be used to form the transmission filter(s) 412 and/or the reception filter(s) 414. An inductor or other matching component 420 may be connected at the common node 402.

The front-end module 400 further includes a transmitter circuit 432 connected to the input node 404 of the duplexer 410 and a receiver circuit 434 connected to the output node 406 of the duplexer 410. The transmitter circuit 432 can generate signals for transmission via the antenna 510, and the receiver circuit 434 can receive and process signals received via the antenna 510. In some embodiments, the receiver and transmitter circuits are implemented as separate components, as shown in FIG. 19, however, in other embodiments these components may be integrated into a common transceiver circuit or module. As will be appreciated by those skilled in the art, the front-end module 400 may include other components that are not illustrated in FIG. 19 including, but not limited to, switches, electromagnetic couplers, amplifiers, processors, and the like.

FIG. 20 is a block diagram of one example of a wireless device 500 including the antenna duplexer 410 shown in FIG. 19. The wireless device 500 can be a cellular phone, smart phone, tablet, modem, communication network or any other portable or non-portable device configured for voice or data communication. The wireless device 500 can receive and transmit signals from the antenna 510. The wireless device includes an embodiment of a front-end module 400 similar to that discussed above with reference to FIG. 19. The front-end module 400 includes the duplexer 410, as discussed above. In the example shown in FIG. 20 the front-end module 400 further includes an antenna switch 440, which can be configured to switch between different frequency bands or modes, such as transmit and receive modes, for example. In the example illustrated in FIG. 20, the antenna switch 440 is positioned between the duplexer 410 and the antenna 510; however, in other examples the duplexer 410 can be positioned between the antenna switch 440 and the antenna 510. In other examples the antenna switch 440 and the duplexer 410 can be integrated into a single component.

The front-end module 400 includes a transceiver 430 that is configured to generate signals for transmission or to process received signals. The transceiver 430 can include the transmitter circuit 432, which can be connected to the input node 404 of the duplexer 410, and the receiver circuit 434, which can be connected to the output node 406 of the duplexer 410, as shown in the example of FIG. 19.

Signals generated for transmission by the transmitter circuit 432 are received by a power amplifier (PA) module 450, which amplifies the generated signals from the transceiver 430. The power amplifier module 450 can include one or more power amplifiers. The power amplifier module 450 can be used to amplify a wide variety of RF or other frequency-band transmission signals. For example, the power amplifier module 450 can receive an enable signal that can be used to pulse the output of the power amplifier to aid in transmitting a wireless local area network (WLAN) signal or any other suitable pulsed signal. The power amplifier module 450 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 450 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 20, the front-end module 400 may further include a low noise amplifier module 460, which amplifies received signals from the antenna 510 and provides the amplified signals to the receiver circuit 434 of the transceiver 430.

The wireless device 500 of FIG. 20 further includes a power management system 520 that is connected to the transceiver 430 and manages the power for the operation of the wireless device 500. The power management system 520 can also control the operation of a baseband sub-system 530 and various other components of the wireless device 500. The power management system 520 can include, or can be connected to, a battery (not shown) that supplies power for the various components of the wireless device 500. The power management system 520 can further include one or more processors or controllers that can control the transmission of signals, for example. In one embodiment, the baseband sub-system 530 is connected to a user interface 540 to facilitate various input and output of voice and/or data provided to and received from the user. The baseband sub-system 530 can also be connected to memory 550 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 5 GHz, such as in a range from about 600 MHz to 2.7 GHz.

### Applications

Although embodiments disclosed herein relate to surface acoustic wave resonators or packages and packaged acoustic wave components, any suitable principles and advantages disclosed herein can be applied to other types of acoustic wave resonators that include an IDT electrode, such as Lamb wave resonators and/or boundary wave resonators. For example, any suitable combination of features of the tilted and rotated IDT electrodes disclosed herein can be applied to a Lamb wave resonator and/or a boundary wave resonator.

Some of the embodiments described above have provided examples in connection with wireless devices or mobile phones. However, the principles and advantages of the embodiments can be used for any other systems or apparatus that have needs for acoustic wave filters.

Such acoustic wave filters can be implemented in various electronic devices. Examples of the electronic devices can include, but are not limited to, consumer electronic products, parts of the consumer electronic products, electronic test equipment, etc. Examples of the electronic devices can also include, but are not limited to, memory chips, memory modules, circuits of optical networks or other communication networks, and disk driver circuits. The consumer electronic products can include, but are not limited to, a mobile phone, a telephone, a television, a computer monitor, a computer, a hand-held computer, a personal digital assistant (PDA), a microwave, a refrigerator, an automobile, a stereo system, a cassette recorder or player, a DVD player, a CD player, a VCR, an MP3 player, a radio, a camcorder, a camera, a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately”, “about”, “generally,” and “substantially” may refer to an amount that is within less than 10% of, within less than 5% of, within less than 1% of, within less than 0.1% of, and within less than 0.01% of the stated amount. As another example, in certain embodiments, the terms “generally parallel” and “substantially parallel” refer to a value, amount, or characteristic that departs from exactly parallel by less than or equal to 15 degrees, 10 degrees, 5 degrees, 3 degrees, 1 degree, or 0.1 degree.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. An acoustic wave resonator comprising:
a multi-layer piezoelectric substrate, the multi-layer piezoelectric substrate including a base layer, an intermediate layer, and a piezoelectric layer, the intermediate layer positioned between the base layer and the piezoelectric layer, the piezoelectric layer including lithium niobate (LiNbO3) having a cut angle in a range from 20 degrees to 40 degrees; and
a plurality of interdigital transducer electrodes in electrical communication with the piezoelectric layer.

2. The acoustic wave resonator of claim 1 wherein the piezoelectric layer includes 30 degrees Y-cut X-propagation lithium niobate (LiNbO3).

3. The acoustic wave resonator of claim 1 wherein a thickness of the intermediate layer is greater than a thickness of the piezoelectric layer.

4. The acoustic wave resonator of claim 1 wherein the piezoelectric layer has a thickness in a range from 0.02 L to 0.38 L, L being a wavelength of a main acoustic wave excited by the acoustic wave resonator.

5. The acoustic wave resonator of claim 1 wherein the intermediate layer includes silicon dioxide (SiO2).

6. The acoustic wave resonator of claim 1 wherein the intermediate layer has a thickness in a range from 0.2 L to 0.6 L, L being a wavelength of a main acoustic wave excited by the acoustic wave resonator.

7. The acoustic wave resonator of claim 1 wherein the plurality of interdigital transducer electrodes have a thickness in a range from 0.04 L to 0.16 L, L being a wavelength of a main acoustic wave excited by the acoustic wave resonator.

8. The acoustic wave resonator of claim 1 wherein tip areas of electrode fingers of the plurality of interdigital transducer electrodes have a greater thickness than a central area of the electrode fingers of the plurality of interdigital transducer electrodes.

9. The acoustic wave resonator of claim 1 wherein tip areas of electrode fingers of the plurality of interdigital transducer electrodes have a greater length than a central area of the electrode fingers of the plurality of interdigital transducer electrodes.

10. The acoustic wave resonator of claim 1 wherein the plurality of interdigital transducer electrodes include aluminum (Al), copper (Cu), molybdenum (Mo), tungsten (W), platinum (Pt), or titanium (Ti).

11. The acoustic wave resonator of claim 1 wherein the plurality of interdigital transducer electrodes include two layers, one layer includes aluminum and the other layer includes molybdenum.

12. The acoustic wave resonator of claim 1 wherein the plurality of interdigital transducer electrodes include a bus bar.

13. The acoustic wave resonator of claim 1 further comprising a partial bottom silicon dioxide (SiO2) layer partially disposed between the multi-layer piezoelectric substrate and the plurality of interdigital transducer electrodes.

14. The acoustic wave resonator of claim 1 further comprising a silicon nitride (SiN) layer disposed on a central area of electrode fingers of the plurality of interdigital transducer electrodes and on an end region of the plurality of interdigital transducer electrodes.

15. The acoustic wave resonator of claim 1 further comprising a silicon dioxide (SiO2) layer disposed on a tip area of electrode fingers of the plurality of interdigital transducer electrodes.

16. The acoustic wave resonator of claim 1 wherein the base layer includes silicon (Si), silicon carbide (SiC), quartz (Qz), Poly-Si/Si compound, a-Si/Si compound, or silicon nitride (SiN/Si) compound.

17. The acoustic wave resonator of claim 1 wherein the multi-layer piezoelectric substrate consists of the base layer, the intermediate layer, and the piezoelectric layer.

18. A radio frequency module comprising an acoustic wave resonator, the acoustic wave resonator comprising:
a multi-layer piezoelectric substrate, the multi-layer piezoelectric substrate including a base layer, an intermediate layer, and a piezoelectric layer disposed on the intermediate layer, the intermediate layer positioned between the base layer and the piezoelectric layer, the piezoelectric layer including lithium niobate (LiNbO3) having a cut angle in a range from 20 degrees to 40 degrees; and
a plurality of interdigital transducer electrodes in electrical communication with the piezoelectric layer.

19. The radio frequency module of claim 18 wherein the radio frequency module is configured as a front end module.

20. A wireless communication device comprising:
a radio frequency module including an acoustic wave resonator, the acoustic wave resonator including: a multi-layer piezoelectric substrate including a base layer, an intermediate layer, and a piezoelectric layer disposed on the intermediate layer, the intermediate layer positioned between the base layer and the piezoelectric layer, the piezoelectric layer including lithium niobate (LiNbO3) having a cut angle in a range from 20 degrees to 40 degrees; and
a plurality of interdigital transducer electrodes in electrical communication with the piezoelectric layer.
